(19) United States
(12) Patent Application Publication
(10) Pub. No.: US 2020/0395399 A1
(43) Pub. Date: Dec. 17, 2020

(54) PACKAGING METHOD AND PACKAGING STRUCTURE FOR SEMICONDUCTOR CHIP

(71) Applicant: China Wafer Level CSP Co., Ltd., Suzhou, Jiangsu (CN)

(72) Inventors: Zhiqi Wang, Suzhou, Jiangsu (CN); Guoliang Xie, Suzhou, Jiangsu (CN); Hanqing Hu, Suzhou, Jiangsu (CN); Wenbin Wang, Suzhou, Jiangsu (CN)

(73) Assignee: China Water Level CSP Co., Ltd., Suzhou, Jiangsu (CN)

(21) Appl. No.: 16/303,722

(22) PCT Filed: May 23, 2017
(86) PCT No.: PCT/CN2017/085450

§ 371 Date: Nov. 21, 2018

(30) Foreign Application Priority Data
May 25, 2016 (CN) 201610351803.0
May 25, 2016 (CN) 201620483572.4

(51) Int. Cl. H01L 27/146

(52) U.S. Cl. CPC H01L 27/14636; H01L 27/14687; H01L 27/14632; H01L 27/14618

(57) ABSTRACT

A packaging method and a packaging structure for a semiconductor chip. The packaging method comprises: providing a wafer, the water being provided with a functional area and solder pads arranged on a first surface; forming vias on a second surface of the wafer, the bottom of the vias exposing the solder pads; forming metal wiring layers at the bottom and on the sidewalls of the vias, the metal wiring layers extending to the second surface of the wafer, the metal wiring layers being electrically connected to the corresponding solder pads; forming a solder mask layer on the second surface of the wafer and in the vias; forming grooves on the solder mask layer at positions corresponding to the vias, the difference between the depth of the grooves and the depth of the vias being 0-20 micrometers. By reducing the amount of the solder mask being filled in the vias, the stress generated by the solder mask layer and acting on the metal wiring layer during a subsequent reliability test is effectively reduced, thus preventing a case in which the metal wiring layers become separated from the solder pads.

This application claims the priority to Chinese Patent Application No. 201610351803.0, titled “PACKAGING METHOD AND PACKAGING STRUCTURE FOR SEMICONDUCTOR CHIP”, filed on May 25, 2016 with the Chinese Patent Office and Chinese Patent Application No. 201620483572.4, titled “PACKAGING STRUCTURE FOR SEMICONDUCTOR CHIP”, filed on May 25, 2016 with the Chinese Patent Office, which are incorporated herein by reference in their entireties.

### FIELD

The present disclosure relates to the technical field of semiconductors, and in particular to a technology for packaging a wafer level semiconductor chip.

### BACKGROUND

According to the wafer level chip size packaging (WLCSP) technology, which is currently the predominant technology for packaging semiconductor chips, a whole wafer is packaged and tested, and then is cut to acquire single finished chips, where the size of the single finished chip packaged using this technology is approximately the same as the size of a single die, thus market requirements for microelectronic products which are increasingly lighter, smaller, shorter, thinner and cheaper can be met. Therefore, the wafer level chip size packaging technology becomes a focus and a development trend of the current field of packaging.

Referring to FIG. 1, a wafer level semiconductor chip package is shown. A wafer 1 is attached with a protective base plate 2, support units 3 are located between the wafer 1 and the protective base plate 2, so that a gap is formed between the wafer 1 and the protective base plate 2 to avoid direct contact between the wafer 1 and the protective base plate 2. The wafer 1 includes multiple semiconductor chips 10 arranged in an array, each of which includes a functional region 11 and contact pads 12. Multiple support units 3 are arranged in an array on the protective base plate 2 and are in one-to-one correspondence with the semiconductor chips 10. After the protective base plate 2 is attached with the wafer 1, the functional region 11 is located in a sealed cavity 13 formed by the support unit 3. The wafer 1 has a first surface and a second surface which are opposite to each other, and the functional regions 11 and the contact pads 12 are located on the first surface of the wafer.

Through holes 22 extending to the first surface the wafer 1 are provided on the second surface of the wafer 1 to electrically connect the contact pads 12 to other circuits. The through holes 22 respectively correspond to the contact pads 12, and the contact pads 12 are exposed at bottoms of the through holes 22. An insulation layer 23 is provided on sidewalls of the through holes 22 and on the second surface of the wafer. Metal wiring layers 24 are provided on the insulation layer 23 and on the bottoms of the through holes 22, where the metal wiring layers 24 are electrically connected to the contact pads 12. Solder balls 25 are provided on the second surface of the wafer and are electrically connected to the metal wiring layers 24. The contact pads 12 are electrically connected to other circuits via the solder balls 25.

Cutting grooves 21 extending to the first surface of the wafer 1 are provided on the second surface of the wafer 1 to facilitate cutting to obtain packaged chips.

Before the bolder balls 25 are provided on the second surface of the wafer 1, a solder mask layer 26 is provided on the second surface of the wafer and in the through holes. The solder mask layer is made of photoresist. Openings are formed on the photoresist by exposing and developing the photoresist. The metal wiring layers 24 are exposed at bottoms of the openings, and the bolder balls 25 are provided in the openings and are electrically connected to the metal wiring layers 24. Generally, the through holes 22 and the cutting grooves 21 are almost fully filled with the photoresist.

However, since the through holes 22 is fully filled with photoresist, the metal wiring layer 24 is subject to stress generated by thermal expansion and cold shrinkage of the photoresist in the through hole 22 during a subsequent reliability test. The metal wiring layer 24 may be separated from the contact pad 12 under this stress, resulting in poor contact between the metal wiring layer 24 and the contact pad 12, with is an urgent technical issue to be solved by those skilled in the art.

### SUMMARY

A method for packaging a wafer level semiconductor chip and a wafer level semiconductor chip package are provided according to the present disclosure to solve the technical issue that the metal wiring layer is prone to be separated from the contact pad, thereby avoiding the poor contact between the metal wiring layer and the contact pad, such that the quality and reliability of the semiconductor chip package can be improved.

To address above issue, a method for packaging a semiconductor chip is provided according to the present disclosure, which includes: preparing a wafer, where the wafer has a first surface and a second surface which are opposite to each other, the wafer is provided with multiple semiconductor chips arranged in an array, each of the multiple semiconductor chips has a functional region and contact pads located on the first surface; forming through holes on the second surface of the wafer, where the through holes extend to the first surface of the wafer, and the contact pads are exposed at bottoms of the through holes; forming metal wiring layers on bottoms and sidewalls of the through holes, where the metal wiring layers extend to the second surface of the wafer and are electrically connected to the contact pads; forming a solder mask layer on the second surface of the wafer and in the through holes, where the solder mask layer covers the metal wiring layers; forming openings on the solder mask layer at positions corresponding to the second surface of the wafer, where the metal wiring layers are exposed at bottoms of the openings; forming solder bumps in the openings, where the solder bumps are electrically connected to the metal wiring layers; and forming grooves on the solder mask layer at positions corresponding to the through holes, where a difference between a depth of the grooves and a depth of the through holes ranges from 0 μm to 20 μm.

Preferably, the solder mask layer uniformly may cover the sidewalls of the through holes, the bottoms of the through holes, and the second surface of the wafer.

Preferably, the solder mask layer may be formed by a spraying process.

Preferably, the solder mask layer may be formed on the second surface of the wafer and in the through holes by a spin-coating process, and the grooves may be formed on the solder mask layer at the positions corresponding to the through holes by an etching process or a laser drilling process.

Preferably, the solder mask layer may have a thickness ranging from 5 μm to 20 μm.

Preferably, before the forming the through holes, the method may further include: preparing a protective base plate, where the protective base plate is provided with support units arranged in an array, and the support units are in one-to-one correspondence with the semiconductor chips; and attaching the first surface of the wafer with the protective base plate, where the support units are located between the wafer and the protective base plate, and the functional region is located in a sealed cavity formed by the support unit.

Preferably, the semiconductor chip may be an image sensing chip, and the functional region has a function of image sensing.

Preferably, before the forming the metal wiring layers on the bottoms and the sidewalls of the through holes, the method may further include: forming an insulation layer on the second surface of the wafer and the sidewalls of the through holes, where the metal wiring layers are formed on the second surface of the wafer, on the insulation layer on the sidewalls of the through holes, and on the bottoms of the through holes.

Preferably, the insulation layer may be made of organic insulation material and may be formed on the second surface of the wafer, and the sidewalls and the bottoms of the through holes by a spraying process or a spin-coating process, and the insulation layer located on the bottoms of the through holes is removed by laser or by exposing and developing, to expose the contact pads located at the bottoms of the through holes.

Preferably, the insulation layer may be made of inorganic insulation material, and may be formed on the second surface of the wafer, and the sidewalls and the bottoms of the through holes by a deposition process, and the insulation layer located on the bottoms of the through holes is removed by an etching process, to expose the contact pads located at the bottoms of the through holes. Buffer layers are provided between the metal wiring layers and the insulation layer at positions corresponding to the solder bumps.

A semiconductor chip package is further provided according to an embodiment of the present disclosure, which includes: a substrate, which has a first surface and a second surface which are opposite to each other; a functional region and contact pads located on the first surface of the substrate; through holes located on the second surface and extending to the first surface, where the contact pads are exposed at bottoms of the through holes; metal wiring layers provided on the bottoms and sidewalls of the through holes, where the metal wiring layers extend to the second surface of the substrate, and are electrically connected to the contact pads; a solder mask layer provided on the second surface of the substrate and in the through holes, where the solder mask layer covers the metal wiring layers; openings provided on the solder mask layer at positions corresponding to the second surface of the substrate, where the metal wiring layers are exposed at bottoms of the openings; solder bumps provided in the openings, and electrically connected to the metal wiring layers; and grooves formed on the solder mask layer at positions corresponding to the through holes, where a difference between a depth of the grooves and a depth of the through holes ranges from 0 μm to 20 μm.

Preferably, the semiconductor chip package may further include: a protective base plate attached with the first surface of the substrate; and a support unit located between the protective base plate and the substrate, where the functional region is located in a sealed cavity formed by the support unit.

Preferably, the solder mask layer may uniformly cover the sidewalls of the through holes, the bottoms of the through holes and the second surface of the substrate.

Preferably, the solder mask layer may have a thickness ranging from 5 μm to 20 μm.

Preferably, the solder mask layer may be made of photoresist.

Preferably, the semiconductor chip may be an image sensing chip, and the functional region may have a function of image sensing.

Preferably, the semiconductor chip package may further include: an insulation layer provided on the second surface of the wafer and on the sidewalls of the through holes, where the metal wiring layers are formed on the second surface of the wafer, on the insulation layer on the sidewalls of the through holes, and on the bottoms of the through holes.

Preferably, the insulation layer may be made of organic insulation material.

Preferably, the insulation layer may be made of inorganic insulation material.

Preferably, the semiconductor chip package may further include: buffer layers provided between the metal wiring layers and the insulation layer at positions corresponding to the solder bumps.

The advantageous effect of the present disclosure is that: the stress received by the metal wiring layer which is generated due to the solder mask layer during a subsequent reliability test is effectively reduced by reducing the amount of solder mask filled in the through hole, thereby preventing the metal wiring layer from being separated from the contact pad, such that the packaging yield of the semiconductor chips can be increased, and the quality and reliability of the semiconductor chip package can be improved.

### BRIEF DESCRIPTION OF THE DRAWINGS

FIG. 1 is a schematic diagram of a wafer level semiconductor chip package according to the conventional technology;

FIG. 2 is a schematic structural diagram of a wafer level semiconductor chip;

FIG. 3 is a cross-sectional view showing a semiconductor chip package according to a preferred embodiment of the present disclosure;

FIG. 4 to 11 are schematic diagrams showing a method for packaging a wafer level semiconductor chip according to a preferred embodiment of the present disclosure; and

FIG. 12 is a schematic diagram of a single semiconductor chip package according to a preferred embodiment of the present disclosure.

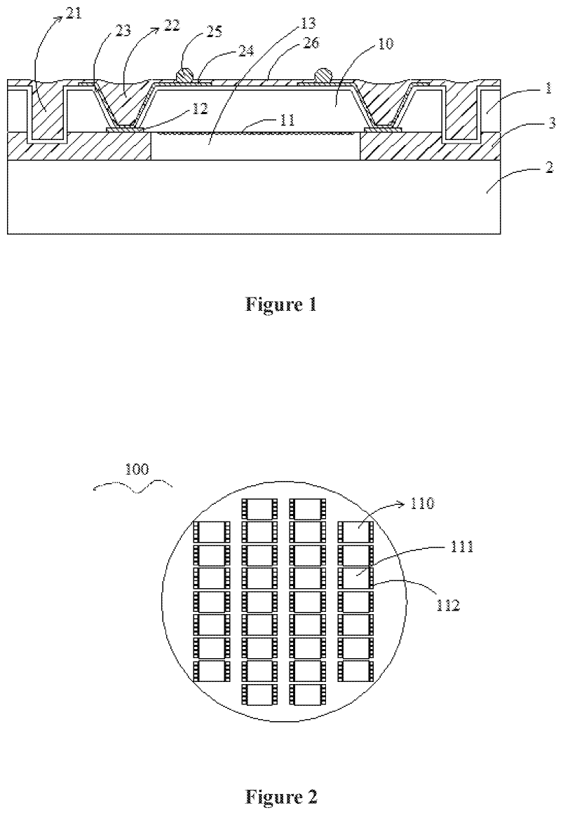

### DETAILED DESCRIPTION OF EMBODIMENTS

The embodiments of the present disclosure are described in detail below in conjunction with the drawings, but the present disclosure is not limited thereto. Various alternations in the structure, the method or in the function made by those skilled in the art based on these embodiments fall in the scope of protection of the present disclosure.

In the conventional technology, the through hole is almost fully filled with the solder mask. Therefore, the metal wiring layer is subject to a stress generated by the expansion or shrinkage of the solder mask layer during a subsequent reliability test, resulting in the metal wiring layer being prone to be separated from the contact pad.

To address above issue, according to the present disclosure, the amount of the solder mask layer filled in the through hole is reduced to effectively reduce the stress generated due to the solder mask layer during the subsequent reliability test, thereby preventing the metal wiring layer from being separated from the contact pad, such that the packaging yield of the semiconductor chips can be increased, and the quality and reliability of the semiconductor chip package can be improved.

Referring to FIG. 2, which is a schematic structural diagram of a wafer level semiconductor chip, a wafer 100 is provided with multiple semiconductor chips 110 arranged in an array. The multiple semiconductor chips 110 are spaced from each other, and are separated from each other along spaces therebetween after subsequent packaging processes and tests are finished.

Each of the semiconductor chips 110 has a functional region 111, and multiple contact pads 112 which located adjacent to sides of the functional region 111 and on the surface of the wafer 100 where the functional region 111 is located.

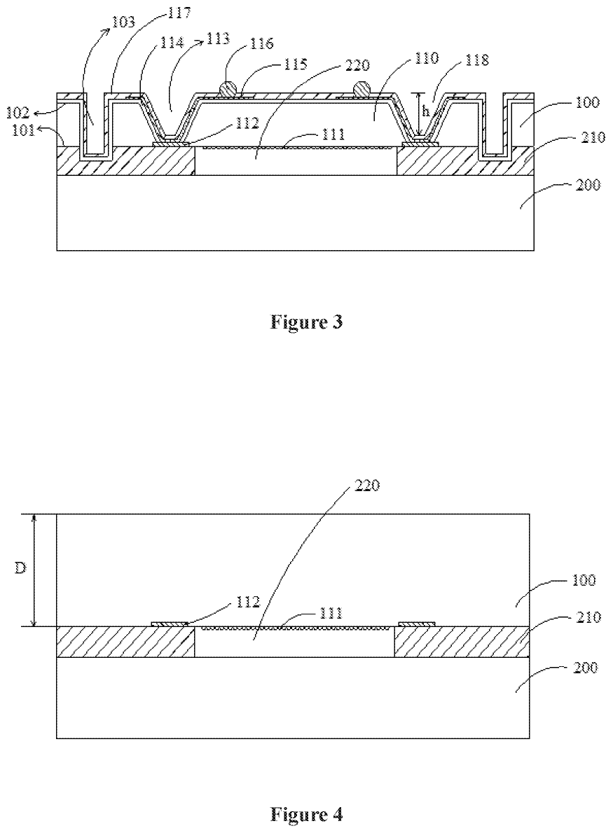

Reference is made to FIG. 3, which is a cross-sectional view showing a wafer level semiconductor chip package according to a preferred embodiment of the present disclosure. Multiple support units 210 are arranged in an array on one surface of the protective base plate 200. After the wafer 100 is attached with the protective base plate 200, the support units 210 are located between the wafer 100 and the protective base plate 200 such that spaces are formed between the wafer 100 and the protective base plate 200. The support units 210 are in one-to-one correspondence with the semiconductor chips 110, and the functional region 111 is located in a sealed cavity 220 formed by the support unit 210.

The wafer 100 has a first surface 101 and a second surface 102 which are opposite to each other. The functional region 111 and the contact pads 112 are located on the first surface 101. Cutting grooves 103 extending to the first surface 101 and through holes 113 extending to the first surface 101 are located on the second surface of the wafer. The positions of the through holes 113 are in one-to-one correspondence with the positions of the contact pads 112, and the contact pads 112 are exposed at bottoms of the through holes 113.

The contact pads 112 are connected to an extemal circuit via metal wiring layers 115 and solder bumps 116. Specifically, an insulation layer 114 is provided on sidewalls of the through holes 113 and on the second surface 102 of the wafer 100. In this embodiment, the insulation layer 114 is made of silicon dioxide, and has a thickness ranging from 2 μm to 5 μm. The metal wiring layers 115 electrically connected to the contact pads 112 are formed on the bottoms and the sidewalls of through holes 113. The metal wiring layers 115 extend to the second 102 surface of the wafer 100 and are located on the insulations layer 114. Solder bumps 116 are provided on the second surface 102 of the wafer 100 and are electrically connected to the metal wiring layers 115. The contact pads 112 are connected to an external circuit through electrical connection between the solder bumps 116 and the external circuit.

A solder mask layer 117 covers the second surface 102 of the wafer 100, sidewalls and bottoms of the cutting grooves 103, as well as the sidewalls and the bottoms of the through holes 113. The solder mask layer 117 is located on the metal wiring layers 115, and is provided with openings at positions corresponding to the second surface 102 of the wafer 100. The metal wiring layers 115 are exposed at bottoms of the openings, and solder bumps 116 are located in the openings and are electrically connected to the metal wiring layers 115.

Grooves 118 are formed on the solder mask layer 117 at positions corresponding to the through holes 113, to reduce the amount of material of the solder mask 117 filled in the through holes 113, such that the stress received by the metal wiring layers 115 which is generated due to the solder mask layer 117 during the subsequent reliability test is reduced, thereby preventing the metal wiring layers 115 from being separated from the contact pads 112.

The depth h of the grooves 118 is approximately equal to the depth H of the through holes. The depth H of the through holes 113 may be greater than the depth of the grooves 118, and the difference between the depth H of the through holes 113 and the depth of the grooves 118 ranges from 0 μm to 20 μm, so that the metal wiring layers 115 can be effectively prevented from being separated from the contact pads 112.

The grooves 118 are formed on the solder mask layer 117 by the following packaging process.

A wafer 100 is provided. The structure of the wafer 100 is shown in FIG. 2.

A protective base plate 200 is provided. One surface of the protective base plate 200 is provided with multiple support units 210 arranged in an array. In this embodiment, the support units 210 are made of photoresist. The support units 210 are formed on one of the surfaces of the protective base plate 200 by coating photoresist on the whole surface and then performing an exposing and developing process. Alternatively, the support units 210 arranged in an array are formed on one of surfaces of the protective base plate 200 by a screen printing process.

Referring to FIG. 4, the wafer 100 is attached with the protective base plate 200 with adhesive gel, such that the support units 210 are located between the wafer 100 and the protective base plate 200. The support units 210 are in one-to-one correspondence with the semiconductor chips 110, and the functional region 111 of the semiconductor chip 110 is located in a sealed cavity 220 formed by the support unit 210.

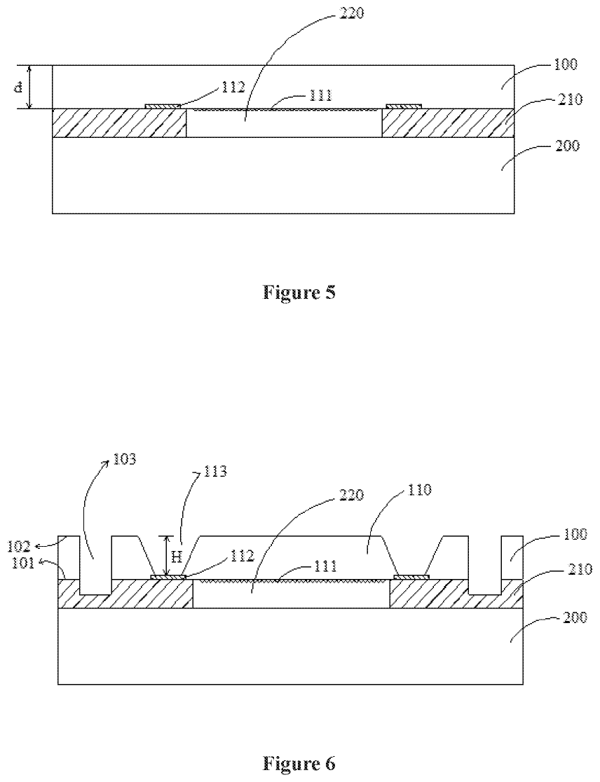

Referring to FIG. 5, the wafer 100 is thinned from the second surface 102 by grinding. The thickness of the wafer 100 before thinning is D (referring to FIG. 4) and the thickness of the wafer 100 after thinning is d.

Referring to FIG. 6, through holes 113 extending to the first surface 101 of the wafer 100 are formed on the second surface 102 of the wafer 100 by an etching process. The depth of the through holes is H. Cutting grooves 103 extending to the first surface 101 of the wafer 100 are formed on the second surface 102 of the wafer 100 by a cutting process. In another embodiment of the present disclosure, the through holes 113 may be formed by etching after the cutting grooves 103 are formed by cutting.

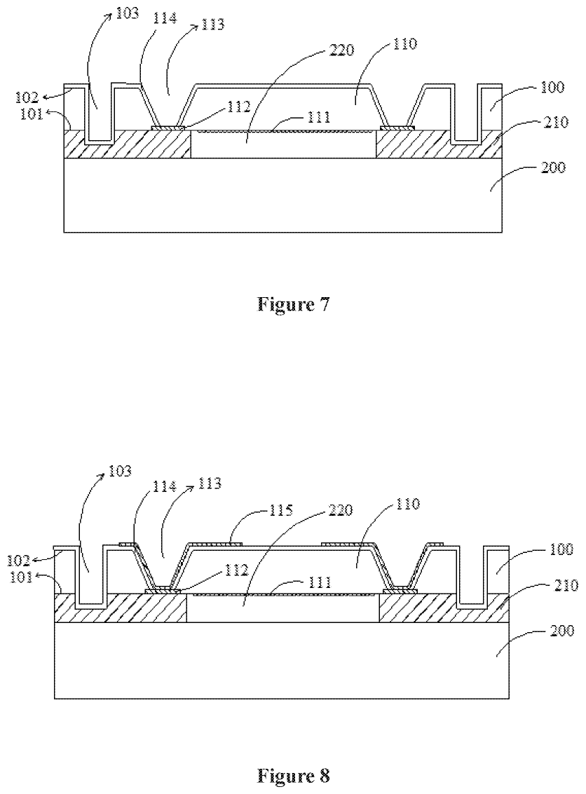

Referring to FIG. 7, an insulation layer 114 is formed on the second surface 102 of the wafer 100, on sidewalls and bottoms of the through holes 113, as well as on sidewalls and bottoms of the cutting grooves 103. In this embodiment, the insulation layer 114 is made of organic insulation material which is insulative and flexible. The insulation layer 114 is formed by a spraying process or a spin-coating process, and then the contact pads 112 are exposed by laser or by exposing and developing.

In another embodiment of the present disclosure, the insulation layer 114 is made of inorganic insulation material which is generally silicon dioxide, and is deposited on the second surface 102 of the wafer 100, on the sidewalls and the bottoms of the through holes 113, as well as on the sidewalls and the bottoms of the cutting grooves 103. Preferably, since the shock resistance of the silicon dioxide is inferior to organic insulation material, buffer layers are formed on the second surface of the wafer 100 at positions corresponding to the solder bumps by an exposing and developing process. The contact pads 112 are exposed by removing the insulation layer on the bottoms of the through holes 113 by an etching process.

Referring to FIG. 8, metal wiring layers 115 are formed on the insulation layer 114. The metal wiring layers 115 are located on the sidewalls and the bottoms of the through holes 113 and extend to the second surface 102 of the wafer 100. The metal wiring layers 115 are electrically connected to the contact pads 112. Preferably, the metal wiring layers 115 have a thickness ranging from 1 μm to 5 μm.

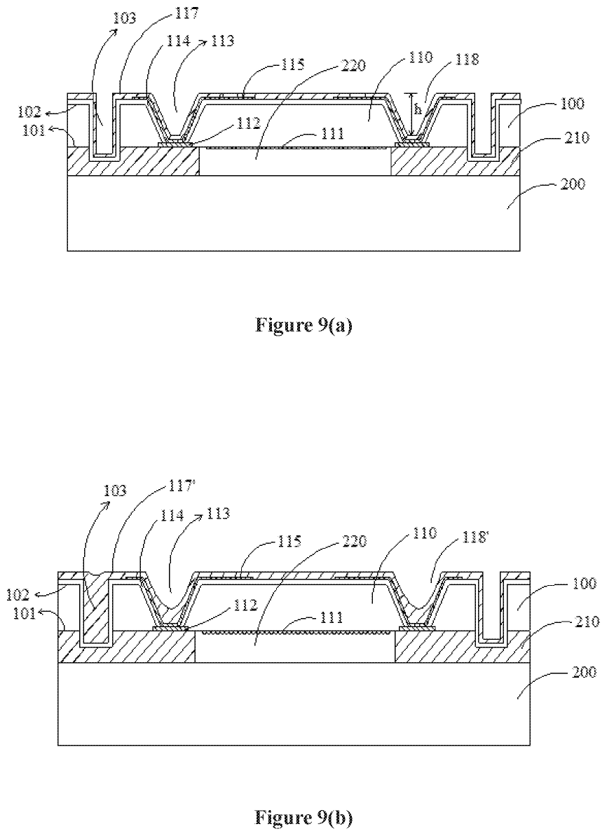

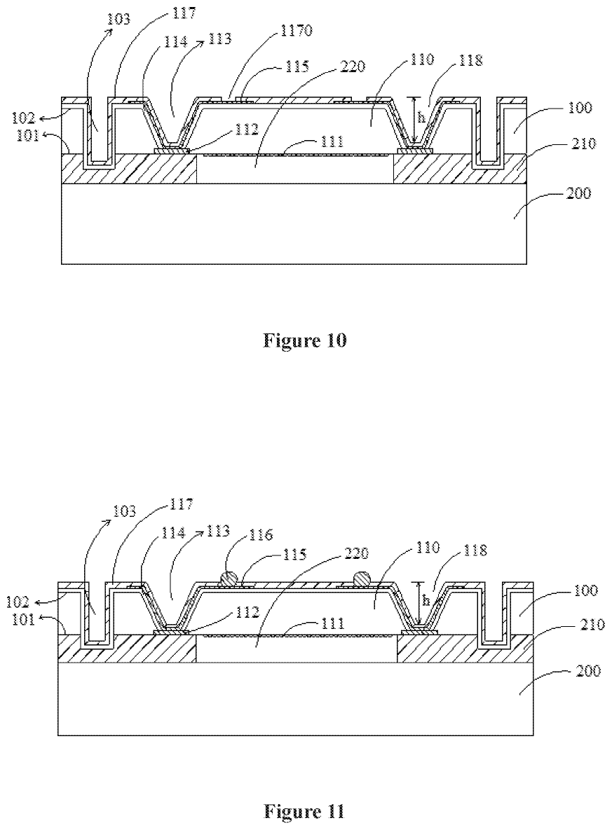

Referring to FIG. 9(a), a solder mask layer 117 with a uniform thickness is formed on the sidewalls and the bottoms of the cutting grooves 103, on the sidewalls and the bottoms of the through holes 113, as well as on the second surface 102 of the wafer 100 by a spraying process, for providing solder resistance and protecting the chip during a subsequent process for forming the solder balls.

In this embodiment, the solder mask layer 117 is made of photoresist generally used in the field of semiconductor technologies.

Due to the uniform thickness of the solder mask layer 117, the grooves 118 are formed on the solder mask layer 117 at positions corresponding to the through holes 113. The depth of the grooves 118 is h. In this embodiment, the depth h of the grooves 118 is approximately equal to the depth H of the through holes.

Since the solder mask layer 117 uniformly covers the sidewalls of the through holes 113, the bottoms of the through holes 113, and the second surface 102 of the wafer 100, the amount of the material of the solder mask layer 117 filled in the through holes 113 is reduced, the stress received by the metal wiring layer 115 which is generated due to the solder mask layer 117 during the subsequent reliability test is reduced, thereby preventing the metal wiring layer 115 from being separated from the contact pads 112.

Preferably, the solder mask layer 117 has a thickness ranging from 5 μm to 20 μm.

Referring to FIG. 9(b), which shows another manner of forming grooves on the solder mask layer at positions corresponding to the through holes. A solder mask layer 117′ is formed on the cutting grooves 103, in the through holes 113 and on the second surface 102 of the wafer 100 by a spin-coating process. The cutting grooves 103 and the through holes 113 are almost fully filled with the solder mask material. Then, grooves 118′ are formed on the solder mask layer 117′ at positions corresponding to the through holes 113 by an etching process or a laser drilling process.

The depth h of the grooves 118 (or the grooves 118′) is approximately equal to the depth H of the through holes 113. The depth H of the through holes 113 may be greater than the depth of the grooves 118 (or the grooves 118′), and the difference between the depth H of the through holes 113 and the depth of the grooves 118 (or the grooves 118′) ranges from 0 μm to 20 μm, so that the metal wiring layers 115 can be prevented from being separated from the contact pads 112.

Referring to FIG. 10, openings are formed on the solder mask layer at positions corresponding to the second surface of the wafer for facilitating subsequent formation of solder bumps. Specifically, openings 1170 are formed on the solder mask layer 117 (or the solder mask layer 117′) by an exposing and developing process, where the metal wiring layers 115 are exposed at bottoms of the openings 1170.

Referring to FIG. 11, solder bumps 116 are formed in the openings 1170 by a ball placement process, where the solder bumps 116 are electrically connected to the metal wiring layers 115.

Finally, the wafer 100 and the protective base plate 200 are cut along the cutting grooves 103 from the second surface 102 of the wafer 100 to the first surface 101 of the wafer 100, to acquire single semiconductor chip packages.

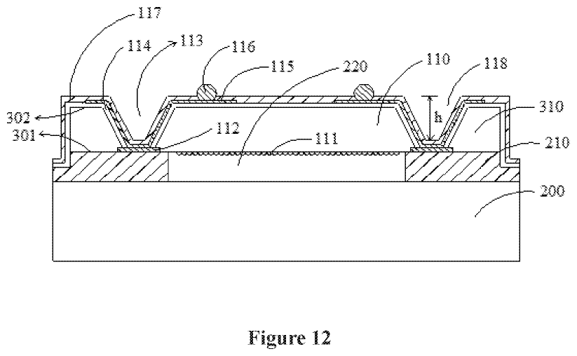

Referring to FIG. 12, the single semiconductor chip package 300 includes a substrate 310 formed by cutting the wafer 100, which has a first surface 301 and a second surface 302 which are opposite to each other. A functional region 111 and contact pads 112 are located on the first surface 301. Through holes 113 and solder bumps 116 are located on the second surface 302. Sidewalls of the substrate 310 are covered by the solder mask layer 117.

If the insulation layer 114 is made of organic insulation material, buffer layers may not be provided between the metal wiring layers 115 and the insulation layer 114 at positions corresponding to the solder bumps 116.

If the insulation layer 114′ is made of inorganic material, buffer layers are provided between the metal wiring layers 115 and the insulation layer 114 at positions corresponding to the solder bumps 116. The buffer layers may be made of photoresist and formed by an exposing and developing process.

The solder mask layer 117 covers the second surface 102 of the wafer 100, the sidewalls and the bottoms of the cutting grooves 103, as well as the sidewalls and the bottoms of the through holes 113. The solder mask layer 117 is located on the metal wiring layers 115, openings are provided on the solder mask layer 117 at positions corresponding to the second surface 102 of the wafer 100, and the metal wiring layers 115 are exposed at bottoms of the openings. The solder bumps 116 are located in the openings and are electrically connected to the metal wiring layers 115.

Grooves 118 are formed on the solder mask layer 117 at positions corresponding to the through holes 113, so that the amount of the material of the solder mask layer 117 filled in the through holes 113 is reduced, the stress received by the metal wiring layers 115 which is generated due to the solder mask layer 117 during the subsequent reliability test is reduced, thereby effectively preventing the metal wiring layers 115 from being separated from the contact pads 112.

The depth h of the grooves 118 is approximately equal to the depth H of the through holes. The depth H of the through holes 113 may be greater than the depth of the grooves 118, and the difference between the depth H of the through holes 113 and the depth of the grooves 118 ranges from 0 μm to 20 μm, so that the metal wiring layers 115 can be effectively prevented from being separated from the contact pads 112.

In this embodiment, the semiconductor chip is an image sensing chip, and the functional region is an image sensing region. Certainly, the semiconductor chip is not limited to an image sensing chip in the present disclosure.

It should be understood that, although the specification is described in embodiments, it is not indicated that each embodiment contains only one independent technical solution. The specification is described in this way only for the purpose of clarity. Those skilled in the art should consider the specification as a whole, and the technical solutions of respective embodiments may be appropriately combined to form other embodiments that can be understood by those skilled in the art.

A series of detailed descriptions above-mentioned are just for illustrating the feasible embodiments of the present disclosure, and are not intend to limit the scope of protection of the present disclosure. Any equivalent embodiments or modifications without departing from the skill and spirit of the present disclosure fall within the scope of protection of the present disclosure.

1. A method for packaging a semiconductor chip, comprising:
preparing a wafer, wherein the wafer has a first surface and a second surface which are opposite to each other, the wafer is provided with a plurality of semiconductor chips arranged in an array, each of the plurality of semiconductor chips has a functional region and contact pads located on the first surface;
forming through holes on the second surface of the wafer, wherein the through holes extend to the first surface of the wafer, and the contact pads are exposed at bottoms of the through holes;
forming metal wiring layers on bottoms and sidewalls of the through holes, wherein the metal wiring layers extend to the second surface of the wafer and are electrically connected to the contact pads;
forming a solder mask layer on the second surface of the wafer and in the through holes, wherein the solder mask layer covers the metal wiring layers;
forming openings on the solder mask layer at positions corresponding to the second surface of the wafer, wherein the metal wiring layers are exposed at bottoms of the openings; and
forming solder bumps in the openings, wherein the solder bumps are electrically connected to the metal wiring layers,
and wherein the method further comprises:
forming grooves on the solder mask layer at positions corresponding to the through holes, a difference between a depth of the grooves and a depth of the through holes ranging from 0 μm to 20 μm.

2. The method for packaging a semiconductor chip according to claim 1, wherein the solder mask layer uniformly covers the sidewalls of the through holes, the bottoms of the through holes, and the second surface of the wafer.

3. The method for packaging a semiconductor chip according to claim 2, wherein the solder mask layer has a thickness ranging from 5 μm to 20 μm.

4. The method for packaging a semiconductor chip according to claim 2, wherein the solder mask layer is formed by a spraying process.

5. The method for packaging a semiconductor chip according to claim 1, wherein the solder mask layer is formed on the second surface of the wafer and in the through holes by a spin-coating process, and the grooves are formed on the solder mask layer at the positions corresponding to the through holes by an etching process or a laser drilling process.

6. The method for packaging a semiconductor chip according to claim 1, wherein before the forming the through holes, the method further comprises:
preparing a protective base plate, wherein the protective base plate is provided with support units arranged in an array, the support units are in one-to-one correspondence with the semiconductor chips; and
attaching the first surface of the wafer with the protective base plate, wherein the support units are located between the wafer and the protective base plate, and the functional region is located in a sealed cavity formed by the support unit.

7. The method for packaging a semiconductor chip according to claim 1, wherein the semiconductor chip is an image sensing chip, and the functional region has a function of image sensing.

8. The method for packaging a semiconductor chip according to claim 1, wherein before the forming the metal wiring layers on the bottoms and the sidewalls of the through holes, the method further comprises:
forming an insulation layer on the second surface of the wafer and the sidewalls of the through holes, wherein the metal wiring layers are formed on the second surface of the wafer, on the insulation layer on the sidewalls of the through holes, and on the bottoms of the through holes.

9. The method for packaging a semiconductor chip according to claim 8, wherein the insulation layer is made of organic insulation material and is formed on the second surface of the wafer, and the sidewalls and the bottoms of the through holes by a spraying process or a spin-coating process, and the insulation layer located on the bottoms of the through holes is removed by laser or by exposing and developing, to expose the contact pads located at the bottoms of the through holes.

10. The method for packaging a semiconductor chip according to claim 8, wherein the insulation layer is made of inorganic insulation material, and is formed on the second surface of the wafer, and the sidewalls and the bottoms of the through holes by a deposition process, and the insulation layer located on the bottoms of the through holes is removed by an etching process, to expose the contact pads located at the bottoms of the through holes.

11. The method for packaging a semiconductor chip according to claim 10, wherein buffer layers are provided between the metal wiring layers and the insulation layer at positions corresponding to the solder bumps.

12. A semiconductor chip package, comprising:
a substrate, which has a first surface and a second surface which are opposite to each other;
a functional region and contact pads located on the first surface of the substrate:
through holes located on the second surface and extending to the first surface, wherein the contact pads are exposed at bottoms of the through holes;
metal wiring layers provided on the bottoms and sidewalls of the through holes, wherein the metal wiring layers extend to the second surface of the substrate, and are electrically connected to the contact pads;
a solder mask layer provided on the second surface of the substrate and in the through holes, wherein the solder mask layer covers the metal wiring layers:
openings provided on the solder mask layer at positions corresponding to the second surface of the substrate, wherein the metal wiring layers are exposed at bottoms of the openings; and
solder bumps provided in the openings, and electrically connected to the metal wiring layers,
wherein the semiconductor chip package further comprises:
grooves formed on the solder mask layer at positions corresponding to the through holes, a difference between a depth of the grooves and a depth of the through holes ranging from 0 μm to 20 μm.

13. The semiconductor chip package according to claim 12, further comprising:
a protective base plate attached with the first surface of the substrate; and
a support unit located between the protective base plate and the substrate, wherein the functional region is located in a sealed cavity formed by the support unit.

14. The semiconductor chip package according to claim 12, wherein the solder mask layer uniformly covers the sidewalls of the through holes, the bottoms of the through holes and the second surface of the substrate.

15. The semiconductor chip package according to claim 14, wherein the solder mask layer has a thickness ranging from 5 μm to 20 μm.

16. The semiconductor chip package according to claim 12, wherein the solder mask layer is made of photoresist.

17. The semiconductor chip package according to claim 12, wherein the semiconductor chip is an image sensing chip, and the functional region has a function of image sensing.

18. The semiconductor chip package according to claim 12, further comprising:
an insulation layer provided on the second surface of the wafer and on the sidewalls of the through holes, wherein the metal wiring layers are formed on the second surface of the wafer, on the insulation layer on the sidewalls of the through holes, and on the bottoms of the through holes.

19. The semiconductor chip package according to claim 18, wherein the insulation layer is made of organic insulation material.

20. The semiconductor chip package according to claim 18, wherein the insulation layer is made of inorganic insulation material.

21. The semiconductor chip package according to claim 20, further comprising:
buffer layers provided between the metal wiring layers and the insulation layer at positions corresponding to the solder bumps.
